(19) United States
(12) Patent Application Publication
(10) Pub. No.: US 2016/0072055 A1
(43) Pub. Date: Mar. 10, 2016

(54) MANUFACTURING METHOD OF SEMICONDUCTOR MEMORY DEVICE

(71) Applicants: Satoshi SETO, Seoul (KR); Shuichi TSUBATA, Seoul (KR); Masatoshi YOSHIKAWA, Seoul (KR); Kazuhiro TOMIOKA, Seoul (KR)

(72) Inventors: Satoshi SETO, Seoul (KR); Shuichi TSUBATA, Seoul (KR); Masatoshi YOSHIKAWA, Seoul (KR); Kazuhiro TOMIOKA, Seoul (KR)

(21) Appl. No.: 14/630,412

(22) Filed: Feb. 24, 2015

Related U.S. Application Data
(60) Provisional application No. 62/047,539, filed on Sep. 8, 2014.

(51) Int. Cl. H01L 43/12; H01L 43/02; H01L 43/08

(52) U.S. Cl. CPC H01L 43/12; H01L 43/08; H01L 43/02

(57) ABSTRACT

According to one embodiment, a manufacturing method of a semiconductor memory device includes the following steps. The method includes forming a first magnetic layer, a second magnetic layer, and an insulating layer therebetween, forming a mask layer on the second magnetic layer, etching the second magnetic layer, the insulating layer, and the first magnetic layer using the mask layer as a mask and forming a magnetic tunnel junction (MTJ) element, and performing oxidation a sidewall of the MTJ element with H₂O.

### CROSS-REFERENCE TO RELATED APPLICATIONS

This application claims the benefit of U.S. Provisional Application No. 62/047,539, filed Sep. 8, 2014, the entire contents of which are incorporated herein by reference.

### FIELD

Embodiments described herein relate generally to a manufacturing method of semiconductor memory device applied to, for example, a magnetoresistive random access memory (NRAM).

### BACKGROUND

MRAM is a general term for nonvolatile semiconductor memory using varying resistance of a barrier layer in accordance with magnetization direction of a ferromagnetic substance. A memory cell of an MRAM comprises a magnetic tunnel junction (MTJ) element using a tunneling magnetoresistive (TMR) effect and transistor. The MTJ element is a three-layered thin film comprising a recording layer and a reference layer, which are formed of magnetic materials, and an insulating layer interposed therebetween. The MTJ element stores data using the magnetization conditions of the recording layer and the reference layer.

In order to achieve a large capacity by miniaturizing the cell size and also a low current, a spin injection MRAM which employs a spin transfer torque (STT) write mode has been proposed. In the spin injection MRAM, data is written to the MTJ element when a current flows in a vertical direction with respect to a film surface of the MTJ element. As the magnetic layer used for the MTJ element, a vertical magnetization film in which the magnetization direction is set in, for example, the vertical direction with respect to the film surface has been proposed.

In order to form an MTJ element, a plurality of magnetic layers and an insulating layer are stacked, and then, a hard mask is formed. Using the hard mask, the plurality of magnetic layers and the insulating layer are etched by ion beam etching (IBE), and the MTJ element is formed.

### BRIEF DESCRIPTION OF THE DRAWINGS

FIG. 1 is a cross-sectional view showing an example of a semiconductor memory device of a present embodiment.

FIG. 2 is a cross-sectional view showing a manufacturing method of the semiconductor memory device of FIG. 1.

FIG. 3 is a cross-sectional view showing the manufacturing process subsequent to FIG. 2.

FIG. 4 is a cross-sectional view showing a manufacturing process subsequent to FIG. 3.

FIG. 5 is a cross-sectional view showing a manufacturing process subsequent to FIG. 4.

FIG. 6 is a cross-sectional view showing a manufacturing process subsequent to FIG. 5.

FIG. 7 is a cross-sectional view showing a general oxidation process.

FIG. 8 is a cross-sectional view showing an oxidation process of the present embodiment.

FIG. 9 is a cross-sectional view showing an oxidation process of a first modification.

FIG. 10 is a cross-sectional view showing an oxidation process of a second modification.

FIG. 11 is a cross-sectional view showing an oxidation process subsequent to FIG. 10.

### DETAILED DESCRIPTION

In general, according to one embodiment, a manufacturing method of a semiconductor memory device includes the following steps. The method includes forming a first magnetic layer, a second magnetic layer, and an insulating layer therebetween, forming a mask layer on the second magnetic layer, etching the second magnetic layer, the insulating layer, and the first magnetic layer using the mask layer as a mask and forming a magnetic tunnel junction (MTJ) element, and performing oxidation a sidewall of the MTJ element with H₂O.

### Embodiment

Hereinafter, embodiments are explained with reference to the accompanying drawings. Throughout the drawings, the same parts are designated by the same reference numbers.

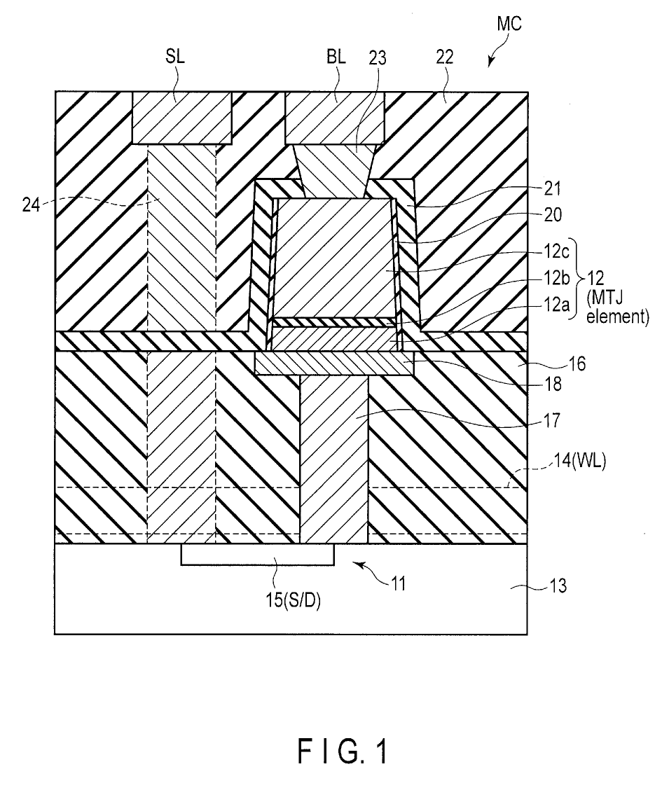

FIG. 1 schematically shows a semiconductor memory device according to the present embodiment, for example, a memory cell MC of MRAM. The memory cell MC is composed of, for example, one transistor and one MTJ element 12. For example, in a silicon substrate 13, a shallow trench isolation (STI) region (not shown) serving as an element isolation region is formed. On the substrate 13, a gate electrode 14 of the transistor 11 is formed via a gate insulating film (not shown). The gate electrode 14 is connected to a gate electrode of an adjacent memory cell (not shown) located in a row direction, and thus forms a word line WL. In the substrate 13 located on both sides of the gate electrode 14, diffusion layers 15 which constitute source/drain (S/D) regions are formed.

On the substrate 13, an interlayer insulating film 16 which covers the transistor 11 is formed, and in the interlayer insulating film 16, a lower contact plug 17 serving as a contact layer and electrically connected to one of the diffusion layers 15 constituting the S/D regions is formed. A lower electrode 18 is formed on the lower contact plug 17. The lower electrode 18 is formed of, for example, tantalum (Ta). An MTJ element 12 is formed on the lower electrode 18.

The MTJ element 12 is composed of, for example, a magnetic layer 12a, barrier layer 12b serving as an insulating layer, and magnetic layer 12c. Magnetic layers 12a and 12c are formed of, for example, CoFeB. The barrier layer 12b is formed of, for example, MgO. Of the magnetic layers 12a and 12c, one whose magnetization direction is fixed is referred to as a fixed layer (reference layer), and one whose magnetization direction is reversed by STT is referred to as a free layer (storage layer). In this embodiment, magnetic layer 12a is, for example, the fixed layer and magnetic layer 12c is, for example, the free layer.

In the present embodiment, the MTJ element 12 is composed of three layers; however, the number of layers is not limited to three and may be modified in various ways. For example, the free layer and the fixed layer may include a cap layer, one of the surfaces of the fixed layer which is not contacting the barrier layer may contact an antimagnetic layer, or the fixed layer may include a first magnetic layer, ruthenium (Ru), and second magnetic layer. Furthermore, the MTJ element 12 may include a first fixed layer, a first barrier layer, a free layer, a second barrier layer, and a second fixed layer.

As explained later, an oxidation film 20 is slightly formed on a sidewall of the MTJ element 12. The oxidation film 20 is formed of an oxide of a material of the MTJ element redeposited at the time when the material of the MTJ element 12 is etched.

The MTJ element 12 is covered with a protective film 21 formed of, for example, silicon nitride film or alumina. An insulating film 22 is formed on the protective film 21, and the upper electrode 23 connected to the MTJ element is formed in a part of the insulating film 22 and the protective film 21. A bit line BL is formed on the upper electrode 23. The bit line BL is arranged to be orthogonal to the word line WL.

Meanwhile, a contact 24 is formed in the interlayer insulating film 16, the protective film 21, and the insulating film 22 those are corresponding to the other diffusion layer 15 of the S/D regions. The contact 24 is electrically connected to the other diffusion layer 15 of the S/D regions. A source line SL is formed on the contact 24. The source line SL is arranged along the bit line BL.

### (Manufacturing Method)

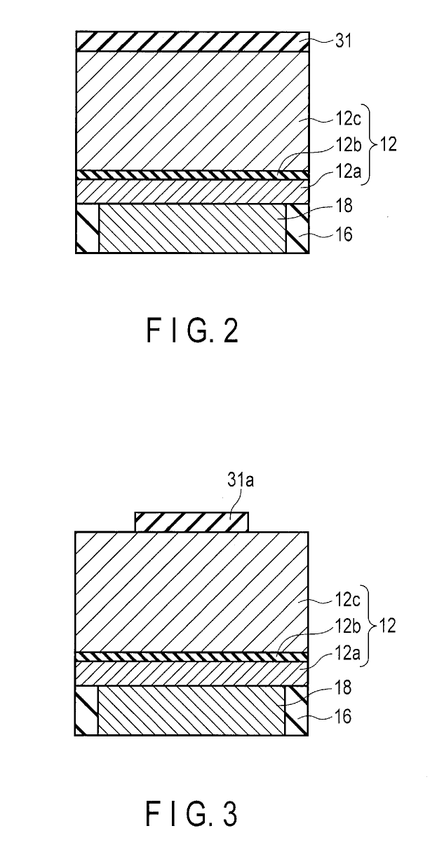

FIGS. 2 to 5 schematically show a manufacturing method of the MTJ element 12 of MRAM according to the present embodiment. In FIGS. 2 to 5, a manufacturing method of transistor or the like formed before the MTJ element 12 is omitted.

As shown in FIG. 2, after the lower electrode 18 is formed inside the interlayer insulating film 16, materials for magnetic layer 12a, barrier layer 12b, and magnetic layer 12c are formed sequentially on the interlayer insulating film 16 and the lower electrode 18. That is, for example, an MgO layer for the barrier layer 12b is formed on a CoFeB layer for magnetic layer 12a, and then, a CoFeB layer for magnetic layer 12c is formed on the MgO layer. Then, a mask material 31 is formed on magnetic layer 12c.

As shown in FIG. 3, the mask material 31 is patterned to form a hard mask 31a.

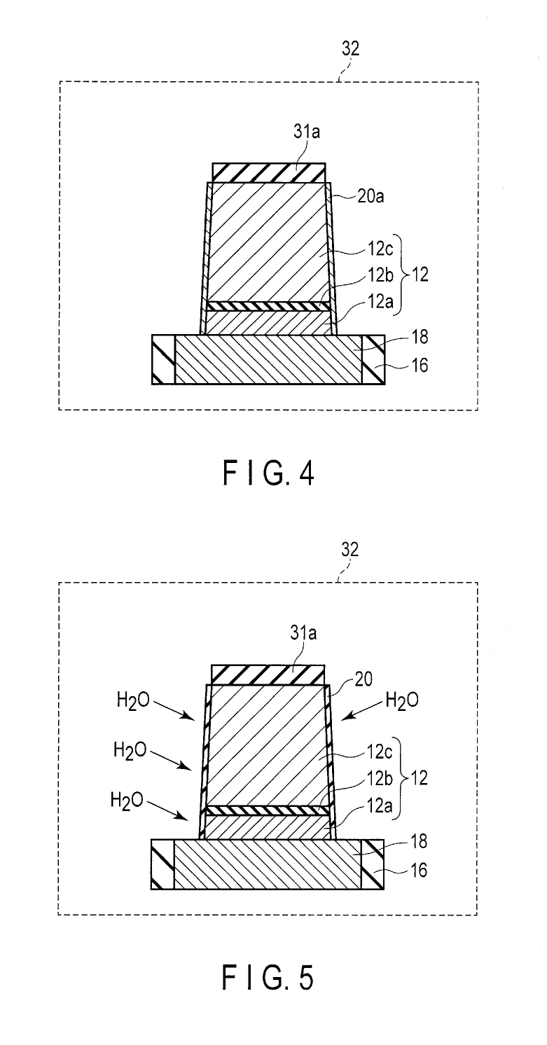

Next, as shown in FIG. 4, in a chamber 32, magnetic layer 12c, barrier layer 12b, and magnetic layer 12a are collectively etched by ion beam etching (IBE) using the hard mask 31a as a mask. Thus, the MTJ element 12 is formed. IBE is a physical etching by sputtering with, for example, argon (Ar) ion. When performing etching, metal elements scattering from magnetic layers 12a and 12c and the barrier layer 12b are redeposited on the sidewall of the MTJ element 12. The deposited substance 20a redeposited on the sidewall of the MTJ element 12 is a slight amount which is not crystallized.

Then, as shown in FIG. 5, for example, a water vapor that is, an H₂O gas (hereinafter simply referred to as H₂O) is introduced into the chamber 32 subjected to IBE to oxidize the deposited substance 20a redeposited on the sidewall of the MTJ element 12 and the sidewall of the MTJ element 12 (hereinafter simply referred to as the sidewall of the MTJ element 12). That is, the IBE process and in-situ oxidation process with H₂O are performed successively. The oxidation process is performed by exposing the wafer to H₂O in a room temperature for 2 to 3 minutes. Through this oxidation process, the sidewall of the MTJ element 12 is oxidized and passivated. That is, the oxidation film 20 is formed on the sidewall of the MTJ element 12.

In the oxidation process, not only H₂O is used but also an inert gas such as argon and nitrogen can be mixed to dilute the H₂O.

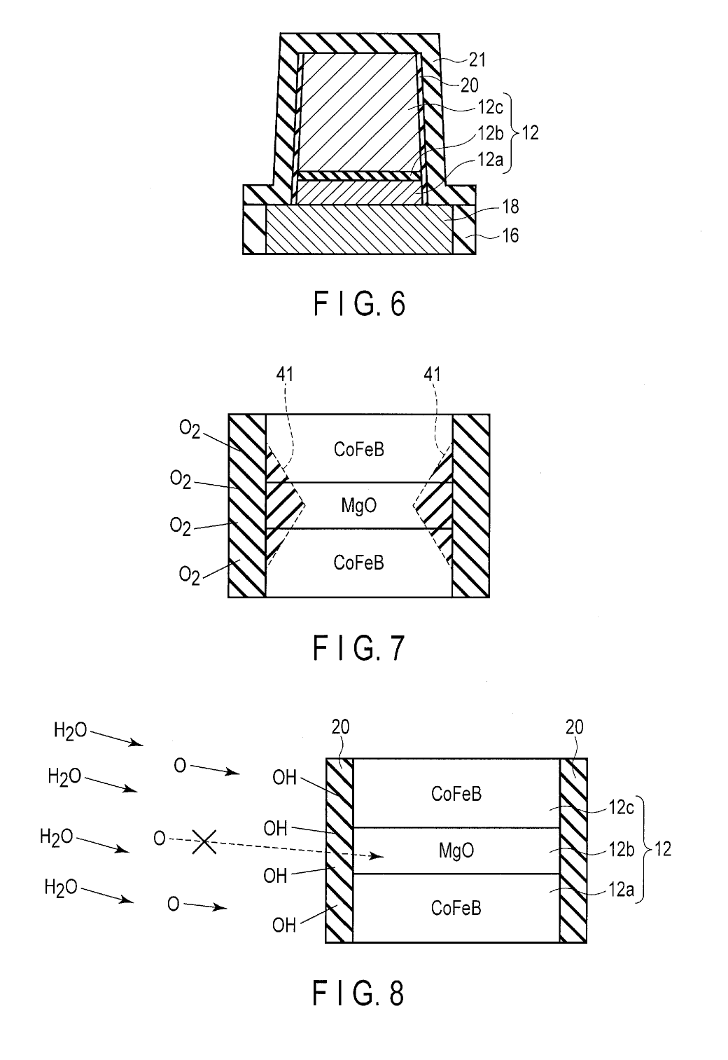

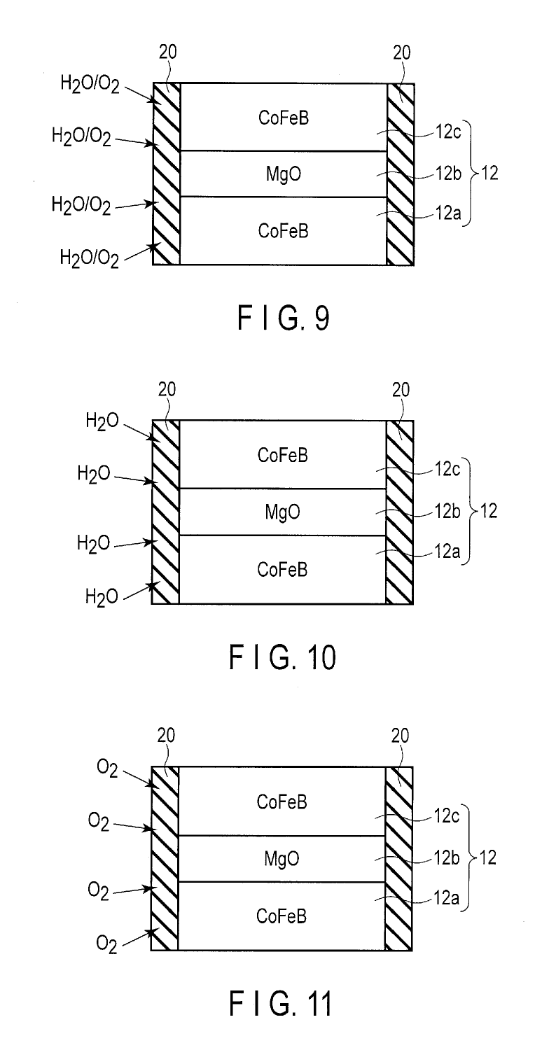

Next, as shown in FIG. 6, after the hard mask 31a is removed, the MTJ element 12 is covered with, for example, a silicon nitride film or a protective film 21 formed of alumina.

### (Advantage)

According to the embodiment, after the MTJ element 12 is formed with IBE, the sidewall of the MTJ element 12 is oxidized with H₂O. The oxidation process of the sidewall of the MTJ element 12 using H₂O can prevent excessive oxidation of the sidewall of the MTJ element 12 compared with the oxidation process with oxygen.

That is, as shown in FIG. 7, the oxidation process with oxygen oxidizes the sidewall of the MTJ element 12 excessively and the sidewall becomes highly resistive. Furthermore, birds' beaks 41 occur within the MTJ element 12 due to such excessive oxidation. Thus, the spin injection efficiency is deteriorated and the magnetization performance of the MTJ element 12 is deteriorated.

In contrast, the oxidation process with H₂O of the present embodiment, as shown in FIG. 8, couples —OH group to a dangling bond of the sidewall of the MTJ element 12 to terminate the dangling bond, and thereby OH group reduces excessive oxygen coupling. Thus, as compared with the oxidation process with oxygen, the excessive oxidation of the sidewall of the MTJ element 12 can be reduced and a resistance value necessary for preventing a shunt defect can be obtained. Furthermore, since the excessive oxidation of the sidewall of the MTJ element 12 can be reduced, birds' beaks in the MTJ element 12 can be prevented. Therefore, the magnetization performance of the MTJ element 12 can be maintained.

Furthermore, the in-situ oxidation process with H₂O of the present embodiment oxidizes the sidewall of the MTJ element 12 after the formation of the MTJ element 12 which used IBE. Thus, by controlling the flow of H₂O, the oxidization can be controlled with high accuracy.

Note that the above oxidation process with H₂O can be performed not only in a room temperature but also in a heated up temperature. That is, a thermal assist oxidation process can be performed. In that case, the temperature is set to 300° C. or below, for example. The thermal assist oxidation can reduce the excessive oxidation of the sidewall of the MTJ element 12 and can prevent birds' beaks in the MTJ element 12.

Furthermore, the same advantage obtained from the thermal assist oxidation process can be achieved, after performing the oxidation process with H₂O in a room temperature, by setting a film forming temperature to, for example, 300° C. when the protective film 21 formed of a silicon nitride film is formed.

Moreover, the oxidation process may be performed using H₂O plasma. The oxidation process with H₂O plasma generates —OH group by plasma assist, unlike —OH group generation by heat, and oxidizes the sidewall of the MTJ element 12.

### (Modification)

In the above embodiment, the sidewall of the MTJ element 12 is oxidized with H₂O; however, the oxidation process is not limited thereto. For example, if the oxidation process with H₂O cannot obtain a full resistance value for preventing a shunt defect, the following modification may be applied.

FIG. 8 schematically shows a first modification in which the sidewall of the MTJ element 12 is oxidized with a mixed gases of H₂O and O₂.

In that case, after the MTJ element 12 is formed by IBE, a mixed gases of H₂O and O₂ is introduced in the chamber subjected to IBE for the in-situ oxidation process. The —OH group contained in the mixed gases of H₂O and O₂ terminates the dangling bond of the sidewall of the MTJ element 12 and oxidizes the sidewall of the MTJ element 12 with O₂. In this modification, an inert gas such as argon and nitrogen can be mixed into the mixed gases.

The advantage obtained in the above embodiment can be achieved in this first modification. Furthermore, in the first modification, The —OH group terminates the dangling bond of the sidewall of the MTJ element 12 and oxidizes the sidewall of the MTJ element 12 with O₂. Thus, in the first modification, the excessive oxidation of the sidewall of the MTJ element 12 can be reduced with H₂O and birds' beaks in the MTJ element 12 can be prevented, and the oxidation with O₂ can achieve a resistance value necessary for preventing a shunt defect.

FIGS. 10 and 11 show a second modification. In the first modification, a mixed gases of H₂O and O₂ is used to oxidize the sidewall of the MTJ element 12. In contrast, in the second modification, the sidewall of the MTJ element 12 is oxidized first with H₂O and then with O₂.

Specifically, as shown in FIG. 10, the MTJ element 12 is first formed by IBE as in the above embodiment, and then, H₂O is introduced into a chamber subjected to IBE. The sidewall of the MTJ element 12 is gradually oxidized with H₂O, and the —OH group terminates the dangling bond on the side surface of the MTJ element 12.

Then, as shown in FIG. 11, O₂ is introduced into the chamber instead of H₂O for further oxidization of the sidewall of the MTJ element 12.

In the above second modification, the oxidation with H₂O and the oxidation with O₂ are performed separately. Thus, the degree of the oxidation can be controlled with more accuracy. Therefore, birds' beaks can be prevented and magnetic performance can be maintained while a sufficient resistance value for preventing a shunt defect can be obtained.

Note that, if a stronger oxidation is necessary than the O₂ oxidation in the second modification, plasma O₂ oxidation process may be used instead of the O₂ oxidation process.

Furthermore, H₂O and O₂ may be diluted by mixing, for example, argon and nitrogen therein.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor memory device, the method comprising:
forming a first magnetic layer, a second magnetic layer, and an insulating layer therebetween;
forming a mask layer on the second magnetic layer;
etching the second magnetic layer, the insulating layer, and the first magnetic layer using the mask layer as a mask and forms a magnetic tunnel junction (MTJ) element; and
performing oxidation a sidewall of the MTJ element with H₂O.

2. The method according to claim 1, wherein
the etching and the oxidation of the MTJ element are performed successively.

3. The method according to claim 2, wherein
the etching and the oxidation of the MTJ element are performed in the same chamber.

4. The method according to claim 1, wherein
the oxidation is performed with a mixed gases of H₂O and an inert gas.

5. The method according to claim 1, wherein
the oxidation is performed with a mixed gases of H₂O and O₂.

6. The method according to claim 1, further comprising performing oxidation with O₂ after the oxidation with H₂O.

7. The method according to claim 1, further comprising performing oxidation with plasma O₂ after the oxidation with H₂O.

8. The method according to claim 1, wherein a sidewall of the MTJ element is oxidized by the oxidation.

9. A manufacturing method of a semiconductor memory device, comprising:
forming a first magnetic layer, a second magnetic layer, and an insulating layer therebetween;
forming a mask layer on the second magnetic layer;
etching the second magnetic layer, the insulating layer, and the first magnetic layer using the mask layer as a mask and forms a magnetic tunnel junction (MTJ) element; and
performing oxidation of substances redeposited on a sidewall of the MTJ element with H₂O.

10. The method according to claim 9, wherein
the forming and the oxidation of the MTJ element are performed successively.

11. The method according to claim 10, wherein
the forming and the oxidation of the MTJ element are performed in the same chamber.

12. The method according to claim 9, wherein
the oxidation is performed with a mixed gases of H₂O and an inert gas.

13. The method according to claim 9, wherein
the oxidation is performed with a mixed gases of H₂O and O₂.

14. The method according to claim 9, further comprising performing oxidation with O₂ after the oxidation with H₂O.

15. The method according to claim 9, further comprising performing oxidation with plasma O₂ after the oxidation with H₂O.

16. The method according to claim 1, further comprising
removing the mask after the oxidation.
